(19) United States
(12) Patent Application Publication
(10) Pub. No.: US 2024/0312943 A1
(43) Pub. Date: Sep. 19, 2024

(54) Channel Manufacturing Method

(71) Applicant: SEIKO EPSON CORPORATION, Tokyo (JP)

(72) Inventor: Junichi OKAMOTO, Shiojiri (JP)

(21) Appl. No.: 18/603,549

(22) Filed: Mar. 13, 2024

(30) Foreign Application Priority Data
Mar. 14, 2023 (JP) 2023-039905

(51) Int. Cl. H01L 23/00; H01L 21/302

(52) U.S. Cl. CPC H01L 24/27; H01L 21/302; H01L 2224/2744; H01L 2924/1517

(57) ABSTRACT

There is provided a channel manufacturing method for performing a first forming step of forming, on a first surface of a first substrate, a slit and a first recess to be separated from each other, a first transfer step of transferring a first adhesive applied to a first substrate for application to the first surface of the first substrate, and a first bonding step of bonding a second substrate to the first surface of the first substrate via the first adhesive.

The present application is based on, and claims priority from JP Application Serial Number 2023-039905, filed Mar. 14, 2023, the disclosure of which is hereby incorporated by reference herein in its entirety.

### BACKGROUND

### 1. Technical Field

The present disclosure relates to a channel manufacturing method.

### 2. Related Art

When a chip for particle capturing is manufactured, a plurality of substrates are joined by transfer of an adhesive to form a channel (see, for example, JP-A-2006-122776. The channel is configured with, for example, stacking substrates in which grooves (slits) are formed to pierce through the substrates.

However, if the thickness of the adhesive between the substrates is excessively large, the adhesive leaks to the outside. This leads to reliability problems in that, for example, a flow of liquid flowing in the channel is disturbed and fluorescent light is emitted during an optical observation to hinder an observation of fluorescent light from cells that is important to distinguish cells included in the liquid.

On the other hand, if the thickness of the adhesive between the substrates is not enough, adhesion strength of the substrates is insufficient. In this case, a problem in manufacturing the chip for particle capturing occurs.

### SUMMARY

The present disclosure presents the following means in order to solve the problems described above.

(1) A first aspect of the present disclosure is a channel manufacturing method for performing: a first forming step of forming, on a first surface of a first substrate, a slit and a first recess to be separated from each other; a first transfer step of transferring a first adhesive applied to a first substrate for application to the first surface of the first substrate; and a first bonding step of bonding a second substrate to the first surface of the first substrate via the first adhesive.

(2) A second aspect of the present disclosure is a channel manufacturing method for performing: a forming step of forming a slit on a first surface of a first substrate; a first transfer step of transferring a first adhesive applied to a first substrate for application to the first surface of the first substrate; and a first bonding step of bonding a second substrate, on a third surface of which a recess is formed, to the first surface of the first substrate via the first adhesive such that the recess is disposed in a vicinity of the slit.

(3) A third aspect of the present disclosure is a channel manufacturing method for performing: a first forming step of forming a slit on a first surface of a first substrate and forming a step section at an opening peripheral edge portion of the slit in the first substrate; a first transfer step of transferring a first adhesive applied to a first substrate for application to the first surface of the first substrate; and a first bonding step of bonding a second substrate to the first surface of the first substrate via the first adhesive.

(4) A fourth aspect of the present disclosure is a channel manufacturing method for performing: a first forming step of forming, on a first surface of a first substrate, a slit and a first recess to be separated from each other; a first application step of applying a first adhesive to an opposite side of the slit with respect to the first recess on the first surface of the first substrate; and a first bonding step of bonding a second substrate to the first surface of the first substrate via the first adhesive.

### BRIEF DESCRIPTION OF THE DRAWINGS

FIG. 1 is a plan view showing an example of a chip for particle capturing manufactured by a channel manufacturing method in a first embodiment of the present disclosure.

FIG. 2 is a sectional view taken along a cutting line A1-A1 in FIG. 1.

FIG. 3 is a plan view of a channel substrate of the chip for particle capturing.

FIG. 4 is a sectional view of an observation part in the chip for particle capturing.

FIG. 5 is a flowchart showing the channel manufacturing method.

FIG. 6 is a sectional view illustrating a manufacturing process for an example of a channel substrate in the channel manufacturing method.

FIG. 7 is a sectional view illustrating the manufacturing process for the example of the channel substrate.

FIG. 8 is a sectional view illustrating the manufacturing process for the example of the channel substrate.

FIG. 9 is a sectional view illustrating the manufacturing process for the example of the channel substrate.

FIG. 10 is a sectional view illustrating a manufacturing process for another example of a channel substrate in the channel manufacturing method.

FIG. 11 is a sectional view illustrating the manufacturing process for the other example of the channel substrate.

FIG. 12 is a sectional view illustrating the manufacturing process for the other example of the channel substrate.

FIG. 13 is a sectional view illustrating a first transfer step in the channel manufacturing method.

FIG. 14 is a sectional view illustrating the first transfer step in the channel manufacturing method.

FIG. 15 is a sectional view illustrating the first transfer step in the channel manufacturing method.

FIG. 16 is a sectional view illustrating a first bonding step in the channel manufacturing method.

FIG. 17 is a sectional view illustrating a second transfer step in the channel manufacturing method.

FIG. 18 is a sectional view illustrating the second transfer step in the channel manufacturing method.

FIG. 19 is a plan view showing an example of a chip for particle capturing manufactured by a channel manufacturing method in a first modification of the first embodiment of the present disclosure.

FIG. 20 is a side sectional view of a chip for particle capturing manufactured by a channel manufacturing method in a second embodiment of the present disclosure.

FIG. 21 is a flowchart showing the channel manufacturing method.

FIG. 22 is a side sectional view of a chip for particle capturing manufactured by a channel manufacturing method in a third embodiment of the present disclosure.

FIG. 23 is a flowchart showing the channel manufacturing method.

FIG. 24 is a side sectional view of a chip for particle capturing manufactured by a channel manufacturing method in a fourth embodiment of the present disclosure.

FIG. 25 is a flowchart showing the channel manufacturing method.

FIG. 26 is a sectional view of an observation part in a chip for particle capturing in a modification.

### DESCRIPTION OF EMBODIMENTS

### First Embodiment

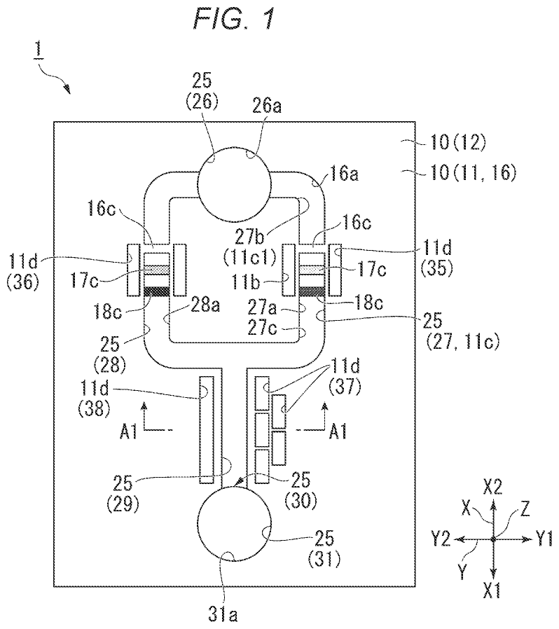

A channel manufacturing method according to a first embodiment of the present disclosure is explained below with reference to FIGS. 1 to 19. In the following explanation, first, a chip for particle capturing manufactured by the channel manufacturing method is explained.

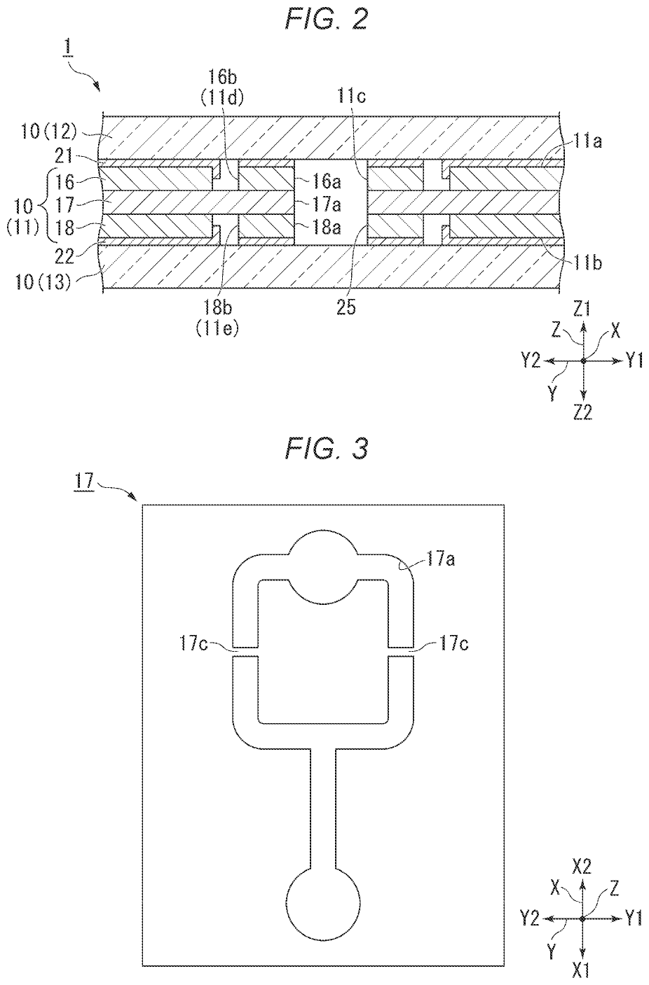

As shown in FIGS. 1 and 2, a chip for particle capturing 1 includes a plurality of substrates 10 in a superimposed state in a thickness direction Z of the plurality of substrates 10.

As shown in FIG. 2, for example, the plurality of substrates 10 includes a second substrate 12, a first substrate 11, and a third substrate 13.

For example, the second substrate 12, the first substrate 11, and the third substrate 13 are formed in a rectangular shape long in a predetermined direction when viewed in the thickness direction Z.

In the following explanation, the second substrate 12 side with respect to the first substrate 11 is referred to as first side Z1 in the thickness direction Z (simply referred to as first side Z1 as well). The third substrate 13 side with respect to the first substrate 11 is referred to as second side Z2 in the thickness direction Z (simply referred to as second side Z2 as well). That is, the second substrate 12, the first substrate 11, and the third substrate 13 are disposed in this order from the first side Z1 toward the second side Z2.

In the following explanation, first, the first substrate 11 is explained.

The first substrate 11 includes channel substrates 16, 17, and 18. The channel substrates 16, 17, and 18 are formed in a rectangular shape long in the predetermined direction when viewed in the thickness direction Z. The channel substrates 16, 17, and 18 are formed of silicon, stainless steel, or the like.

The channel substrates 16, 17, and 18 are disposed in this order from the first side Z1 to the second side Z2.

For example, the thickness of the channel substrates 16, 17, and 18 are 0.1 mm or less. Note that the number of channel substrates in the first substrate 11 is not limited and may be four or more.

Grooves 16a and 16b piercing through the channel substrate 16 in the thickness direction Z are formed in the channel substrate 16. The grooves 16a and 16b are separated from each other.

Similarly, a groove 17a is formed in the channel substrate 17. Grooves 18a and 18b are formed in the channel substrate 18.

The grooves 16a, 17a, and 18a are grooves communicating with one another in the thickness direction Z. The widths of the grooves 16a, 17a, and 18a are the same degree.

The grooves 16b and 18b are grooves partitioned by the channel substrate 17 in the thickness direction Z. The grooves 16b and 18b are disposed to face each other in the thickness direction Z across the channel substrate 17.

Note that the groove 16a extends in an extending direction conforming to the shape of a channel 25 explained in detail below. However, as shown in FIG. 1, in the channel substrate 16, a bridge 16c is provided in a part in a direction in which the groove 16a extends.

Similarly, a bridge 17c is provided in the channel substrate 17 and a bridge 18c is provided in the channel substrate 18. Note that, in FIG. 1, the bridges 17c and 18c are hatched. The bridges 16c, 17c, and 18c are disposed with positions shifted in the extending direction. Consequently, when sample fluid explained below flows in the grooves 16a, 17a, and 18a, the bridges 16c, 17c, and 18c less easily become obstacles.

As shown in FIG. 3, the groove 17a and the bridge 17c are formed in the channel substrate 17.

The channel substrates 16, 17, and 18 are joined to one another by a publicly-known joining method.

As shown in FIG. 2, a slit 11c formed on a first surface 11a facing the first side Z1 in the substrate 11 is configured with the grooves 16a, 17a, and 18a communicating with one another. The slit 11c pierces through the channel substrates 16, 17, and 18 in the thickness direction Z. The slit 11c reaches a second surface 11b on the opposite side of the first surface 11a in the first substrate 11.

A first recess 11d formed on the first surface 11a of the first substrate 11 is configured with the groove 16b and the channel substrate 17. The first recess 11d is separated from the slit 11c.

A second recess 11e formed on the second surface 11b of the first substrate 11 is configured with the groove 18b and the channel substrate 17. The second recess 11e is separated from the slit 11c. The second recess 11e faces the first recess 11d across the channel substrate 17.

The substrates 12 and 13 are formed of transparent glass or the like.

The second substrate 12 is disposed on the first side Z1 of the channel substrate 16. The second substrate 12 and the channel substrate 16 are bonded by a first adhesive 21.

The third substrate 13 is disposed on the second side Z2 of the channel substrate 18. The third substrate 13 and the channel substrate 18 are bonded by a second adhesive 22.

For the first adhesive 21 and the second adhesive 22, a silicone adhesive, an epoxy adhesive, an acrylic adhesive, a phenolic adhesive, a vinyl acetate adhesive, a chloroprene rubber adhesive, and a nitrile rubber adhesive can be used.

As shown in FIGS. 1 and 2, the first side Z1 and the second side Z2 of the slit 11c are closed by the second substrate 12 and the third substrate 13, whereby a sample fluid supply section 26, a first branch channel 27, a second branch channel 28, a merging channel 29, an observation section 30, and a separation section 31, which are channels 25, are formed in the chip for particle capturing 1.

Further, in the chip for particle capturing 1, branch side recesses 35 and 36 and merging side recesses 37 and 38, which are first recesses 11d, are formed. Although not shown, in the chip for particle capturing 1, a branch side recess and a merging side recess, which are second recesses 11e, are formed.

Here, as shown in FIG. 1, the predetermined direction is defined as a longitudinal direction X. A direction orthogonal to the longitudinal direction X and the thickness direction Z is defined as a latitudinal direction Y.

The sample fluid supply section 26 is formed in a columnar shape. The sample fluid supply section 26 is disposed at a first end portion in the longitudinal direction X and in the center in the latitudinal direction Y in the first substrate 11.

An opening section 26a communicates with the sample fluid supply section 26. For example, the opening section 26a is formed in the second substrate 12.

In the following explanation, a second end portion side with respect to the first end portion in the longitudinal direction X in the first substrate 11 is referred to as first side X1 in the longitudinal direction X (in the following explanation, simply referred to as first side X1 as well). The opposite side of the first side X1 in the longitudinal direction X is referred to as second side X2 in the longitudinal direction X (in the following explanation, simply referred to as second side X2 as well).

When viewed in the thickness direction z, the first branch channel 27 is curved to be convex toward a first side Y1 in the latitudinal direction Y (in the following explanation, simply referred to as first side Y1 as well). Specifically, the first branch channel 27 includes a linear section 27a and curved sections 27b and 27c.

The linear section 27a extends in the longitudinal direction X. The curved sections 27b and 27c respectively have quadrant arc shapes. For example, a curvature radius in the center in the width direction of the linear section 27a is 10 mm or more and a curvature radius in the center in the width direction of the curved sections 27b and 27c is less than 10 mm.

The curved section 27b is curved to be convex in a direction between the first side Y1 and the second side X2. The end portion on the first side X1 of the curved section 27b communicates with the end portion on the second side X2 of the linear section 27a.

The curved section 27c is curved to be convex in a direction between the first side Y1 and the first side X1. The end portion on the second side X2 of the curved section 27c communicates with the end portion on the first side X1 of the linear section 27a.

The slit 11c configuring the first branch channel 27 includes a curved section 11c1 in a position corresponding to the curved section 27b.

The end portion on the second side X2 in the first branch channel 27 communicates with the sample fluid supply section 26 from the first side Y1 of the sample fluid supply section 26.

When viewed in the thickness direction z, the second branch channel 28 is curved to be convex toward a second side Y2 on the opposite side of the first side Y1 in the latitudinal direction Y (in the following explanation, simply referred to as second side Y2 as well). The end portion on the second side X2 in the second branch channel 28 communicates with the sample fluid supply section 26 from the second side Y2 of the sample fluid supply section 26.

The end portion on the first side X1 in the second branch channel 28 communicates with the end portion on the second side X2 in the first branch channel 27.

The merging channel 29 extends toward the first side X1 from portions communicating with each other in the branch channels 27 and 28.

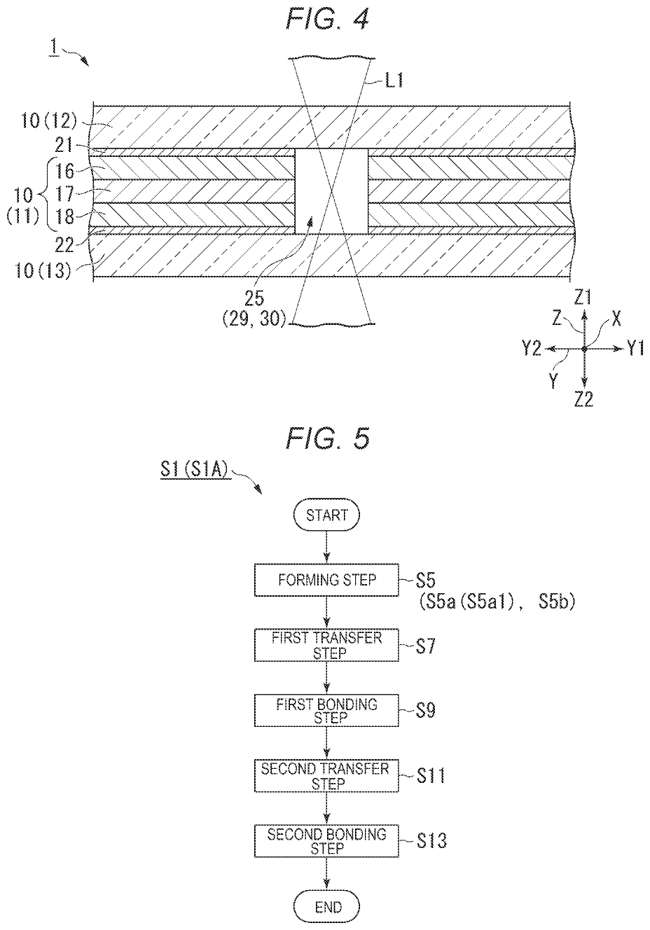

The observation section 30 is provided at the end portion on the first side X1 of the merging channel 29. As shown in FIG. 4, the observation section 30 transmits a laser beam L1 from the outside of the chip for particle capturing 1 to the merging channel 29. That is, the substrates 12 and 13 in a portion corresponding to the observation section 30 are transparent. In this example, the laser beam L1 is transmitted through the observation section 30 in the thickness direction Z.

As shown in FIG. 1, the separation section 31 is formed in a columnar shape. The separation section 31 is provided on the first side X1 of the end portion (the observation section 30) on the first side X1 of the merging channel 29. An opening section 31a communicates with the separation section 31. For example, the opening section 31a is formed in the second substrate 12.

A plurality of branch side recesses 35 are formed in the chip for particle capturing 1. The branch side recesses 35 extend in the longitudinal direction X. The plurality of branch side recesses 35 are disposed to sandwich, in a position separated from the linear section 27a, in the latitudinal direction Y, the linear section 27a extending in the longitudinal direction X in the first branch channel 27. The distance between the first branch channel 27 and the branch side recesses 35 is preferably equal to or smaller than a quintuple of the width of the first branch channel 27 (the slit 11c).

A plurality of branch side recesses 36 are formed in the chip for particle capturing 1. The branch side recesses 36 extend in the longitudinal direction X. The plurality of branch side recesses 36 are disposed to sandwich, in a position separated from a linear section 28a, in the latitudinal direction Y, the linear section 28a extending in the longitudinal direction X in the second branch channel 28.

A plurality of merging side recesses 37 are formed in the chip for particle capturing 1. For example, the plurality of merging side recesses 37 are disposed zigzag further on the first side Y1 than the merging channel 29. More specifically, parts of the plurality of merging side recesses 37 are disposed at intervals from one another in the longitudinal direction X. The remaining parts of the plurality of merging side recesses 37 are disposed to correspond to, further on the first side Y1 than the part of the plurality of merging side recesses 37 and in the longitudinal direction X, parts among the merging side recesses 37 adjacent to one another in the longitudinal direction X in the parts of the plurality of merging side recesses 37.

The merging side recess 38 extends in the longitudinal direction X. The merging side recess 38 is disposed further on the second side Y2 than the merging channel 29.

For example, the groove 16a corresponding to the channel 25 and the groove 16b corresponding to the first recess 11d are formed in the channel substrate 16. The grooves 18a and 18b that are the same as the groves 16a and 16b are formed in the channel substrate 18.

On the other hand, as shown in FIG. 3, the groove 17a corresponding to the channel 25 is formed in the channel substrate 17.

Subsequently, a channel manufacturing method for manufacturing the chip for particle capturing 1 configured as explained above is explained. FIG. 5 is a flowchart showing a channel manufacturing method S1.

First, in a forming step (step S5 shown in FIG. 5), the first substrate 11 is manufactured. In this example, individually manufactured channel substrates 16, 17, and 18 are joined to one another. Note that a method of manufacturing the first substrate 11 in the forming step is not limited to this.

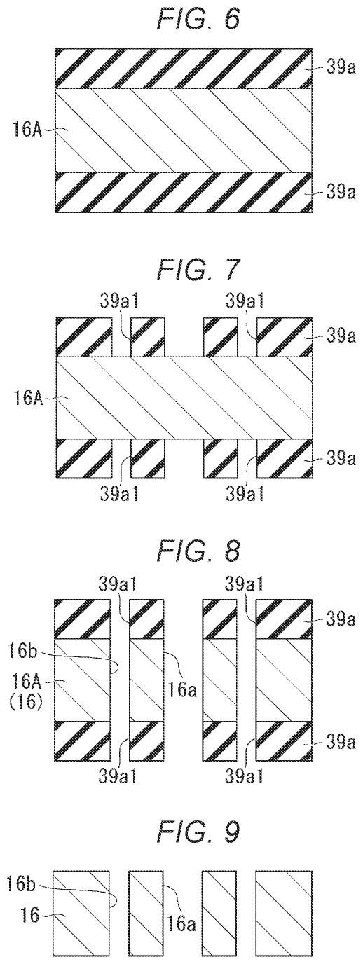

Specifically, in order to manufacture the channel substrate 16, as shown in FIG. 6, a channel substrate 16A before formation of the grooves 16a and 16b in the channel substrate 16 is used. To manufacture the channel substrate 16 from the channel substrate 16A, publicly-known photolithography or the like is used. Resists 39a are provided on both surfaces of the channel substrate 16A by a spin coater or the like.

Although not shown, an ultraviolet ray or the like is irradiated through a mask by exposure. As shown in FIG. 7, through-holes 39a1 are formed in the resists 39a.

As shown in FIG. 8, the grooves 16a and 16b are formed in portions of the channel substrate 16A corresponding to the through-holes 39a1 of the resists 39a by etching.

As shown in FIG. 9, the resists 39a are peeled from the channel substrate 16.

The channel substrate 16 is manufactured by the process explained above. The channel substrate 18 is manufactured by the same process as the process for manufacturing the channel substrate 16.

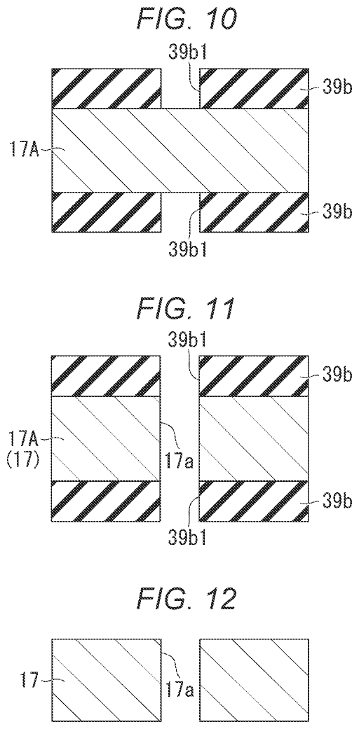

In order to manufacture the channel substrate 17, as shown in FIG. 10, a channel substrate 17A before formation of the groove 17a in the channel substrate 17 is used. Resists 39b are provided on both surfaces of the channel substrate 17A. Through-holes 39b1 are formed in the resists 39b.

As shown in FIG. 11, the grooves 17a are formed in portions of the channel substrate 17A corresponding to the through-holes 39b1 of the resists 39b.

As shown in FIG. 12, the resists 39b are peeled from the channel substrate 17.

The channel substrate 17 is manufactured by the process explained above.

The first substrate 11 is manufactured by joining the manufactured channel substrates 16, 17, and 18 to one another.

In the forming step S5, a first forming step S5a and a second forming step S5b shown in FIG. 5 are performed. In the first forming step S5a, the slit 11c and the first recess 11d are formed to be separated from each other on the first surface 11a of the first substrate 11. In the first forming step S5a, a plurality of first recesses 11d are formed for the plurality of merging side recesses 37. The plurality of first recesses 11d are formed zigzag.

In the second forming step S5b, the second recess 11e is formed to be separated from the slit 11c on the second surface 11b of the first substrate 11.

Which step of the first forming step S5a and the second forming step S5b may be performed first. Both the steps may be simultaneously performed.

When the forming step S5 ends, the channel manufacturing method S1 shifts to step S7.

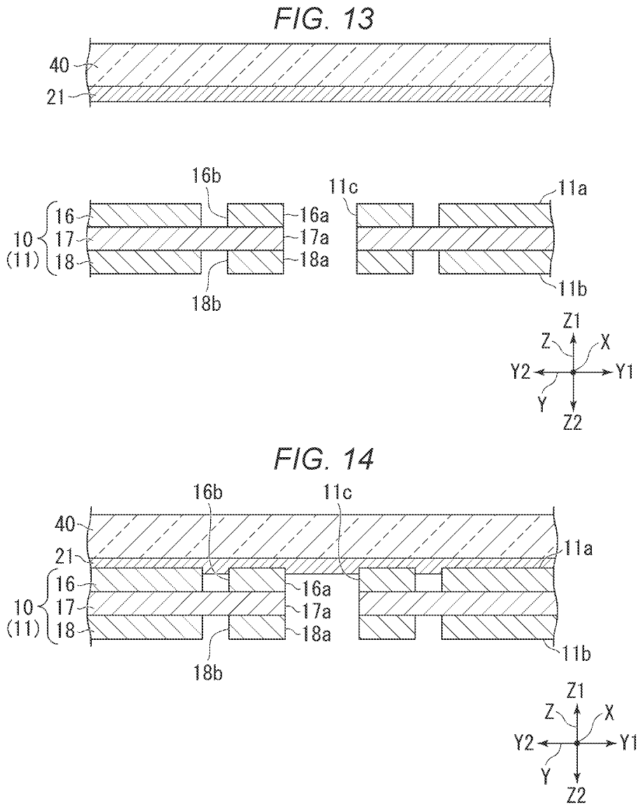

Subsequently, as shown in FIG. 13, in a first transfer step S7, the first adhesive 21 is provided on a first substrate for application 40 by a spin coater or the like.

The first adhesive 21 applied to the first substrate for application 40 is transferred to the first surface 11a of the first substrate 11. For the first substrate for application 40, a glass substrate, annular olefin polymer (COC or COP), polycarbonate (PC), acrylic resin (PMMA), and the like that are optically transparent and having less autofluorescence can be used.

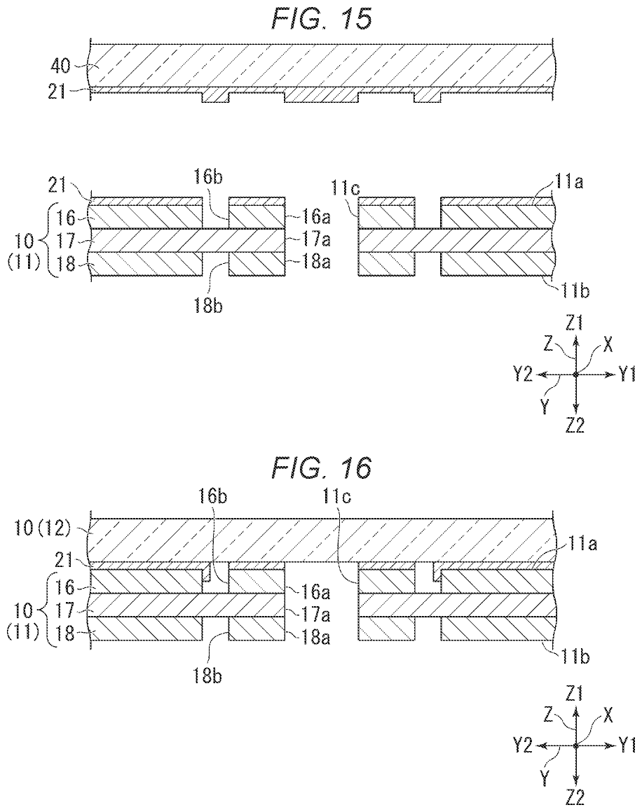

Specifically, as shown in FIG. 14, the first substrate for application 40 is brought close to the first surface 11a of the first substrate 11 and the first adhesive 21 applied to the first substrate for application 40 is deposited on the first surface 11a of the first substrate 11. As shown in FIG. 15, the first substrate for application 40 is separated from the first surface 11a of the first substrate 11 and the first adhesive 21 is transferred to the first surface 11a of the first substrate 11.

When the first transfer step S7 ends, the channel manufacturing method S1 shifts to step S9.

Subsequently, as shown in FIG. 16, in a first bonding step S9, the second substrate 12 is bonded to the first surface 11a of the first substrate 11 via the first adhesive 21.

The first forming step S5a, the first transfer step S7, and the first bonding step S9 are performed in this order. When the first bonding step S9 ends, the channel manufacturing method S1 shifts to step S11.

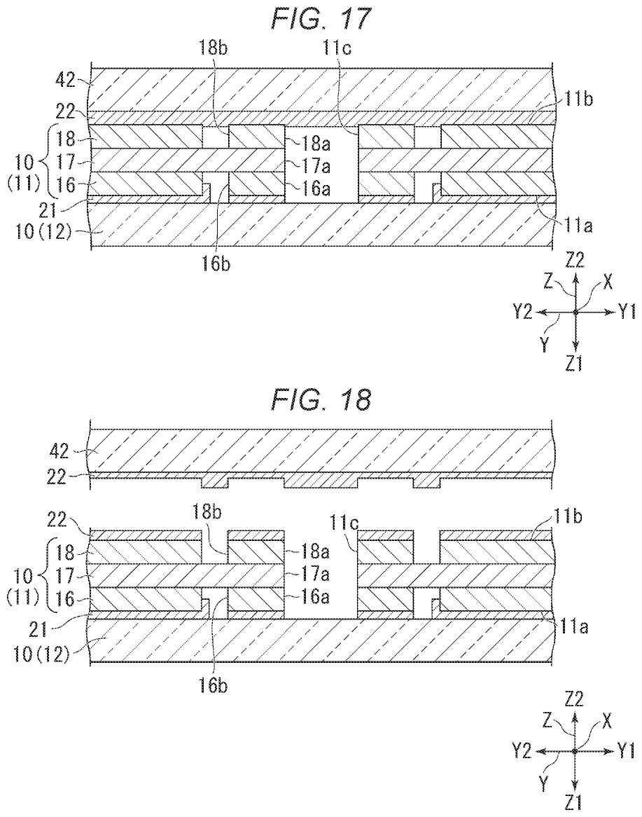

Subsequently, in a second transfer step S11, the second adhesive 22 applied to a second substrate for application 42 is transferred to the second surface 11b of the first substrate 11. Specifically, as shown in FIG. 17, the second substrate for application 42 is brought close to the second surface 11b of the first substrate 11 and the second adhesive 22 applied to the second substrate for application 42 is deposited on the second surface 11b of the first substrate 11. As shown in FIG. 18, the second substrate for application 42 is separated from the second surface 11b of the first substrate 11 and the second adhesive 22 is transferred to the second surface 11b of the first substrate 11.

When the second transfer step S11 ends, the channel manufacturing method S1 shifts to step S13.

Subsequently, in a second bonding step S13, as shown in FIG. 2, the third substrate 13 is bonded to the second surface 11b of the first substrate 11 via the second adhesive 22. The channel 25 is formed by the slit 11c of the first substrate 11, the second substrate 12, and the third substrate 13.

The second forming step S5b, the second transfer step S11, and the second bonding step S13 are performed in this order. When the second bonding step S13 ends, all the steps of the channel manufacturing method S1 end and the chip for particle capturing 1 is manufactured.

Note that the second forming step S5b may not be performed in the channel manufacturing method S1.

Subsequently, an operation of the chip for particle capturing configured as explained above is explained.

When the chip for particle capturing 1 is used, a not-shown supply tube is coupled to the opening section 26a. A not-shown supply pump is coupled to the supply tube.

When the supply pump is driven, sample fluid is supplied to the sample fluid supply section 26 through the supply tube and the opening section 26a. For example, the sample fluid is fluid including cells such as a serum.

The sample fluid flows toward the first side X1 in the branch channels 27 and 28 and merges in the merging channel 29. The sample fluid is observed by the laser beam L1 in the observation section 30.

The observed sample fluid flows into the separation section 31. The sample fluid flowing into the separation section 31 is treated as appropriate.

As explained above, in the channel manufacturing method S1 in this embodiment, in the first transfer step S7, for example, a part of the first adhesive 21 excessively adhering between the first recess 11d and the slit 11c and on the opposite side of the slit 11c with respect to the first recess 11d on the first surface 11a of the first substrate 11 enters the first recess 11d.

Therefore, it is possible to prevent the first adhesive 21 from entering the slit 11c.

In the first forming step S5a, the plurality of first recesses 11d are formed. The plurality of first recesses 11d are formed zigzag. Therefore, when the plurality of first recesses 11d are formed, it is possible to prevent the strength of the first substrate 11 from decreasing. Since the first adhesive 21 enters the plurality of first recesses 11d, the first adhesive 21 is prevented from easily peeling from the first substrate 11 by an anchoring effect.

In the channel manufacturing method S1, the second forming step S5b, the second transfer step S11, and the second bonding step S13 are performed. Consequently, in the second transfer step S11, a part of the second adhesive 22 excessively adhering between the second recess 11e and the slit 11c and on the opposite side of the slit 11c with respect to the second recess 11e on the second surface 11b of the first substrate 11 enters the second recess 11e.

Therefore, it is possible to prevent the second adhesive 22 from entering the slit 11c.

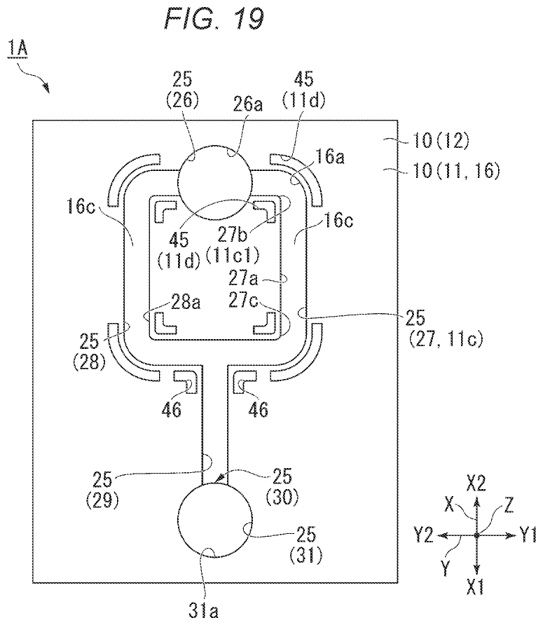

Note that, as in a chip for particle capturing 1A in a first modification shown in FIG. 19, branch side recesses 45 may be formed in the vicinity of the curved sections 27b of the first branch channel 27 instead of the branch side recesses 35 and 36 and the merging side recesses 37 and 38 among the components of the chip for particle capturing 1. Note that, in FIG. 19, the bridges 16c, 17c, and 18c are not shown. The branch side recesses 45 are disposed to hold the curved sections 27b on a plane orthogonal to the thickness direction Z.

In the chip for particle capturing 1A, branch side recesses 46 are formed in a portion where the branch channels 27 and 28 and the merging channel 29 communicate.

As shown in FIG. 5, in a channel manufacturing method S1A in the first modification for manufacturing the chip for particle capturing 1A in the first modification, a first forming step S5a1 is performed instead of the first forming step S5a of the channel manufacturing method S1.

In the first forming step S5a1, the slit 11c is formed to include the curved section 11c1 and the first recess 11d is formed in the vicinity of the curved section 11c1. The vicinity of the curved section 11c1 referred to herein means, for example, a range twice as large as the length in the width direction of the curved section 11c1 on each of the first side and the second side in the width direction based on the center in the width direction of the curved section 11c1.

In general, an adhesive easily enters a curved section when a chip for particle capturing is manufactured.

In the first forming step S5a1, by forming the first recess 11d in the vicinity of the curved section 11c1, it is possible to more surely prevent the first adhesive 21 from entering the slit 11c. The branch side recesses 46 are the same as the branch side recesses 45.

Note that, in the first forming step S5a in this embodiment, a range in which the plurality of first recesses 11d are formed zigzag is not limited. For example, the plurality of first recesses 11d may be formed zigzag on both of the first side Y1 and the second side Y2 of the merging channel 29.

### Second Embodiment

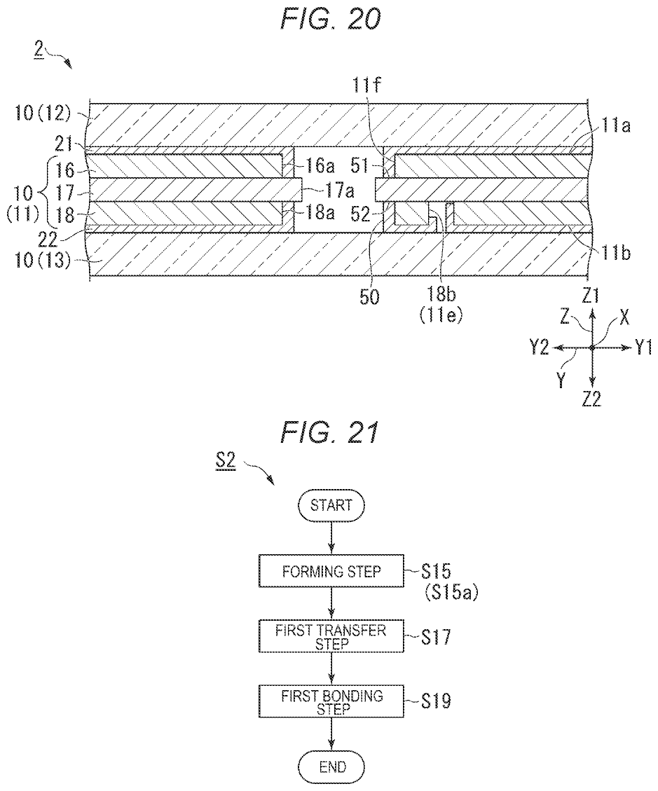

Subsequently, a second embodiment of the present disclosure is explained with reference to FIGS. 20 and 21. However, the same parts as the parts in the first embodiment are denoted by the same reference numerals and signs and explanation of the parts is omitted. Only differences from the first embodiment are explained.

As shown in FIG. 20, a chip for particle capturing 2 manufactured by a channel manufacturing method in this embodiment includes a channel 50 instead of the channel 25 and the groove 16b among the components of the chip for particle capturing 1. The channel 50 is configured with a slit 11f of the first substrate 11, the second substrate 12, and the third substrate 13.

In the chip for particle capturing 2, the width of the grooves 16a and 18a is larger than the width of the groove 17a. The slit 11f is formed on the first surface 11a of the first substrate 11 by the grooves 16a, 17a, and 18a of the channel substrates 16, 17, and 18.

A first step section (a step section) 51 is formed at an opening peripheral edge portion on the first surface 11a side of the slit 11f in the first substrate 11 by the grooves 16a and 17a of the channel substrates 16 and 17. A second step section 52 is formed at an opening peripheral edge portion on the second surface 11b side of the slit 11f in the first substrate 11 by the grooves 17a and 18a of the channel substrates 17 and 18.

Subsequently, a channel manufacturing method for manufacturing the chip for particle capturing 2 configured as explained above is explained. FIG. 21 is a flowchart showing a channel manufacturing method S2.

In the channel manufacturing method S2, first, in a forming step (step S15 shown in FIG. 21) , the slit 11f, the first step section 51, and the second step section 52 are formed on the first surface 11a of the first substrate 11.

In the forming step S15, a first forming step S15a is performed. In the first forming step S15a, the slit 11f is formed on the first surface 11a of the first substrate 11 and the first step section 51 is formed at an opening peripheral edge portion of the slit 11f in the first substrate 11.

When the forming step S15 ends, the channel manufacturing method S2 shifts to step S17.

Subsequently, in a first transfer step S17, the first adhesive 21 applied to the first substrate for application 40 is transferred to the first surface 11a of the first substrate 11. Since the step sections 51 and 52 are formed in the slit 11f, the first adhesive 21 entering in the slit 11f accumulates in the first step section 51 and the slit 11f is less easily closed.

When the first transfer step S17 ends, the channel manufacturing method S2 shifts to step S19.

Subsequently, in a first bonding step S19, the second substrate 12 is bonded to the first surface 11a of the first substrate 11 via the first adhesive 21.

When the first bonding step S19 ends, a second transfer step and a second bonding step that are the same as the first transfer step S17 and the first bonding step S19 are performed, whereby all the steps of the channel manufacturing method S2 end and the chip for particle capturing 2 is manufactured.

As explained above, in the channel manufacturing method S2 in this embodiment, for example, a part of the first adhesive 21 excessively adhering to the first surface 11a of the first substrate 11 in the first transfer step S17 accumulates in the first step section 51 in the first bonding step S19. Therefore, it is possible to prevent the slit 11f from being closed by the first adhesive 21 entering the slit 11f.

Note that the second step section 52 may not be formed in the forming step S15.

### Third Embodiment

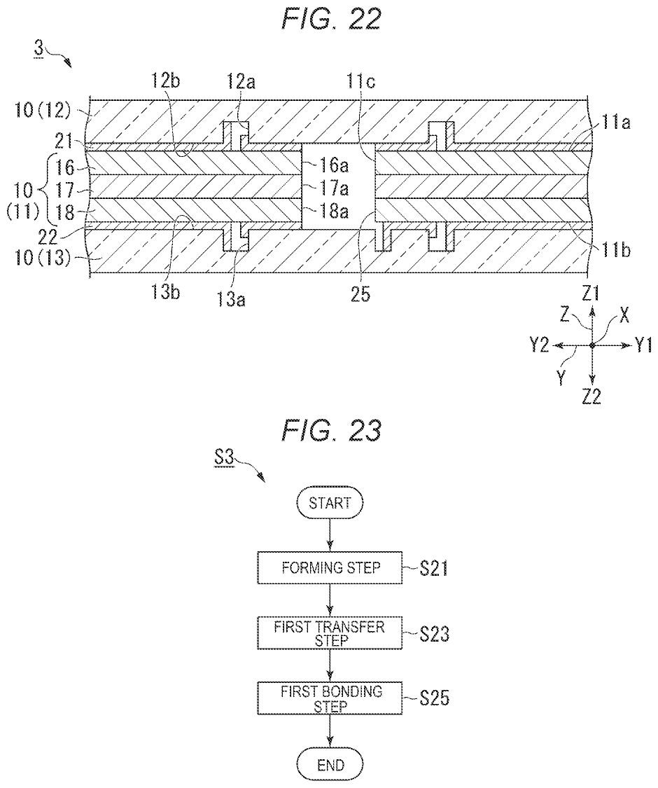

Subsequently, a third embodiment of the present disclosure is explained with reference to FIGS. 22 and 23. However, the same parts as the parts in the embodiments explained above are denoted by the same reference numerals and signs and explanation of the parts is omitted. Only differences from the embodiments explained above are explained.

As shown in FIG. 22, in a chip for particle capturing 3 manufactured by a channel manufacturing method in this embodiment, a first recess (a recess) 12a is formed in the second substrate 12 and a second recess 13a is formed in the third substrate 13 instead of the grooves 16a and 18b among the components of the chip for particle capturing 1.

The first recess 12a is formed on a third surface 12b of the second substrate 12. The second recess 13a is formed on a fourth surface 13b of the third substrate 13.

Subsequently, a channel manufacturing method for manufacturing the chip for particle capturing 3 configured as explained above is explained. FIG. 23 is a flowchart showing a channel manufacturing method S3.

In the channel manufacturing method S3, first, in a forming step (step S21 shown in FIG. 23), the slit 11c is formed on the first surface 11a of the first substrate 11.

When the forming step S21 ends, the channel manufacturing method S3 shifts to step S23.

Subsequently, in a first transfer step S23, the first adhesive 21 applied to the first substrate for application 40 is transferred to the first surface 11a of the first substrate 11.

When the first transfer step S23 ends, the channel manufacturing method S3 shifts to step S25.

Subsequently, in a first bonding step S25, the second substrate 12 is bonded to the first surface 11a of the first substrate 11 via the first adhesive 21 such that the first recess 12a is disposed in the vicinity of the slit 11c of the second substrate 12. The vicinity of the slit 11c referred to herein means, for example, a range five times as large as the length in the width direction of the slit 11c on each of the first side and the second side in the width direction based on the center in the width direction of the slit 11c.

When the first bonding step S25 ends, a second transfer step and a second bonding step that are the same as the first transfer step S23 and the first bonding step S25 are performed, whereby all the steps of the channel manufacturing method S3 end and the chip for particle capturing 3 is manufactured.

As explained above, in the channel manufacturing method S3 in this embodiment, in the first bonding step S25, the first adhesive 21 enters the first recess 12a of the second substrate 12. Therefore, it is possible to prevent the first adhesive 21 from entering the slit 11c.

Note that the second recess 13a may not be formed in the third substrate 13.

### Fourth Embodiment

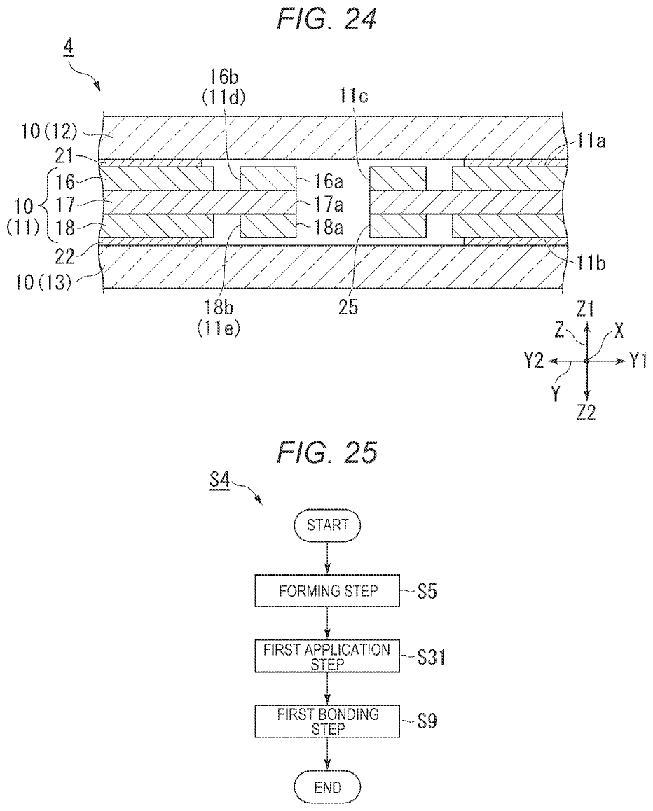

Subsequently, a fourth embodiment of the present disclosure is explained with reference to FIGS. 24 and 25. However, the same parts as the parts in the embodiments explained above are denoted by the same reference numerals and signs and explanation of the parts is omitted. Only differences from the embodiments explained above are explained.

As shown in FIG. 24, a chip for particle capturing 4 manufactured by a channel manufacturing method in this embodiment is different in a range in which the adhesives 21 and 22 are disposed among the components of the chip for particle capturing 1.

The first adhesive 21 is disposed on the opposite side of the slit 11c with respect to the first recess 11d on the first surface 11a of the first substrate 11. The second adhesive 22 is disposed on the opposite side of the slit 11c with respect to the second recess 11e on the second surface 11b of the first substrate 11.

Subsequently, a channel manufacturing method for manufacturing the chip for particle capturing 4 configured as explained above is explained. FIG. 25 is a flowchart showing a channel manufacturing method S4.

First, the forming step S5 is performed. When the forming step S5 ends, the channel manufacturing method S4 shifts to step S31.

Subsequently, in a first application step S31, the first adhesive 21 is applied to the opposite side of the slit 11c with respect to the first recess 11d on the first surface 11a of the first substrate 11. Publicly-known silk printing or the like can be used to control a range in which the first adhesive 21 is applied.

When the first application step S31 ends, the first bonding step S9 is performed.

When the first bonding step S9 ends, a second application step and a second bonding step that are the same as the first application step S31 and the first bonding step S9 are performed, whereby all the steps of the channel manufacturing method S4 end and the chip for particle capturing 4 is manufactured.

As explained above, in the channel manufacturing method S4 in this embodiment, in the first application step S31, the first adhesive 21 is applied to the opposite side of the slit 11c with respect to the first recess 11d on the first surface 11a of the first substrate 11. Therefore, it is possible to prevent the first adhesive 21 from entering the slit 11c.

The first embodiment to the fourth embodiment of the present disclosure are explained above in detail with reference to the drawings. However, a specific configuration is not limited to the embodiments. Changes, combinations, deletions, and the like of the configurations in a range not departing from the gist of the present disclosure are also included in the present disclosure. Further, it goes without saying that the configurations explained in the embodiments can be combined as appropriate and used.

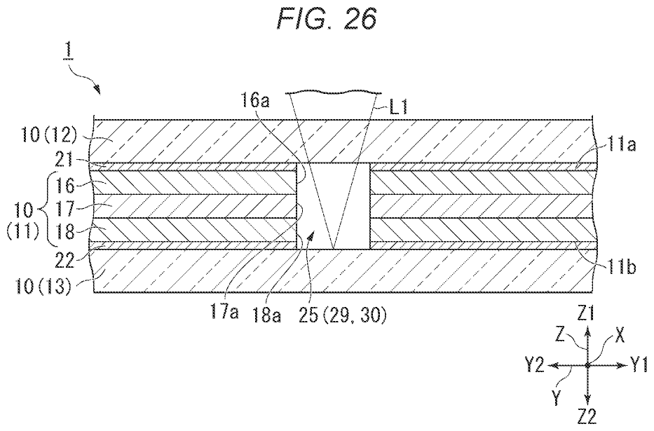

For example, in the chip for particle capturing 1 in the first embodiment, as shown in FIG. 26, the third substrate 13 in the observation section 30 may not be transparent. In this case, in the observation section 30, sample fluid is observed by reflecting the laser beam L1 on the third substrate 13.

The chips for particle capturing in the second embodiment to the fourth embodiment are the same as the chip for particle capturing 1.

What is claimed is:

1. A channel manufacturing method for performing:
a first forming step of forming, on a first surface of a first substrate, a slit and a first recess to be separated from each other;
a first transfer step of transferring a first adhesive applied to a first substrate for application to the first surface of the first substrate; and
a first bonding step of bonding a second substrate to the first surface of the first substrate via the first adhesive.

2. The channel manufacturing method according to claim 1, wherein, in the first forming step, a plurality of the first recesses are formed, and the plurality of first recesses are formed zigzag.

3. The channel manufacturing method according to claim 1, wherein, in the first forming step, the slit is formed to include a curved section and the first recess is formed in a vicinity of the curved section.

4. The channel manufacturing method according to claim 1, wherein the channel manufacturing method further performs:
a second forming step of forming, on a second surface on an opposite side of the first surface in the first substrate, a second recess to be separated from the slit;
a second transfer step of transferring a second adhesive applied to a second substrate for application to the second surface of the first substrate; and
a second bonding step of bonding a third substrate to the second surface of the first substrate via the second adhesive and forming a channel with the slit of the first substrate, the second substrate, and the third substrate.

5. A channel manufacturing method for performing:
a forming step of forming a slit on a first surface of a first substrate;
a first transfer step of transferring a first adhesive applied to a first substrate for application to the first surface of the first substrate; and
a first bonding step of bonding a second substrate, on a third surface of which a recess is formed, to the first surface of the first substrate via the first adhesive such that the recess is disposed in a vicinity of the slit.

6. A channel manufacturing method for performing:
a first forming step of forming a slit on a first surface of a first substrate and forming a step section at an opening peripheral edge portion of the slit in the first substrate;
a first transfer step of transferring a first adhesive applied to a first substrate for application to the first surface of the first substrate; and
a first bonding step of bonding a second substrate to the first surface of the first substrate via the first adhesive.
